(19) United States
(12) Patent Application Publication
(10) Pub. No.: US 2017/0062793 A1
(43) Pub. Date: Mar. 2, 2017

(54) CONTACTOR ASSEMBLY FOR BATTERY MODULE

(71) Applicant: Elitise LLC, Tucson, AZ (US)

(72) Inventors: Kagum G. ZAKHARYAN, Tucson, AZ (US); Sergei N. BEGLIAROV, Tucson, AZ (US); Spiro POULIS, Tucson, AZ (US)

(73) Assignee: Elitise LLC, Tucson, AZ (US)

(21) Appl. No.: 15/198,747

(22) Filed: Jun. 30, 2016

Related U.S. Application Data
(63) Continuation of application No. PCT/US16/40303, filed on Jun. 30, 2016.
Application No. PCT/US16/40303 is a continuation-in-part of application No. PCT/US15/04586, filed on Aug. 24, 2015.
Application No. PCT/US15/04586 is a continuation-in-part of application No. 14/985,774, filed on Dec. 31, 2015, now Pat. No. 9,472,794.

(51) Int. Cl. H01M 2/34; H01L 27/088; H01M 10/42

(52) U.S. Cl. CPC H01M 2/34; H01M 10/425; H01L 27/088; H01M 2010/4271

(57) ABSTRACT

A contactor with a control terminal, first terminal and a second terminal that each extends through the contactor housing, the switch first terminal and the switch second terminal connected to the contactor first terminal and the contactor second terminal, respectively, and the switch control input coupled to the contactor control terminal and capable of allowing or prohibiting current flow between the contactor first terminal and the contactor second terminal.

### FIELD OF THE INVENTION

The present invention relates to battery module architectures and components thereof that facilitate use of battery chemistries, such as lithium-based batteries, that are intended as replacements for lead-acid based batteries. Additionally, the present invention relates to electrical and mechanical components that facilitate improved management of battery modules.

### BACKGROUND OF THE INVENTION

Lithium based batteries have grown in popularity over lead-acid batteries due to their relatively small size and weight compared to lead-acid batteries of similar capacity. Although common in small devices such as cellular phones and cameras, lithium based battery use is becoming more common to power larger loads such as electric cars.

An enclosed battery module, such as those used to start internal combustion engines, typically consist of multiple battery cells coupled together to meet the power requirements of the application. For example, in a battery application requiring 12 VDC, a battery module may consist of four battery cells of at least 3 volts electrically coupled together in series to sum the cell voltages for the battery module. Several lead acid battery cells may be “stacked” or connected electrically in series by a simple conductor to sum the individual cell voltages to create a lead acid battery module that meets the vehicle power requirements. When the vehicle is started, current is drawn from the lead acid battery module to power the starter motor and start the internal combustion engine. Starting operations result in a significant power drain that replenished by an alternator that recharges the battery module to power engine electronics and future vehicle starts. This simple but effective system however is not sufficient for all battery technologies. Lithium-Ion batteries for example present special challenges for vehicle installations and in other similar applications where the re-charge voltage and current are less than constant. Lithium-Ion batteries have low tolerance for overcharge and should be charged with controlled voltage and current to deter degradation or damage to the cells.

Generally, equalization of the battery cell charges during charging operations avoids battery cell over-charge. Lithium-Ion battery systems therefore commonly include smart circuitry that compares and balances the charge on each Lithium-Ion battery cells to prevent overcharge of individual battery cells during charging operations. One common prior art solution includes battery cell balancing circuitry that is coupled to the individual battery cells and that permits controlled discharge of individual battery cells. The battery cell balancing circuitry samples and compares each of the individual battery cell voltages to each of the other battery cell voltages (or a reference voltage) and balances or discharges individual battery cells having charges that exceed the lowest charged battery cell. This technique typically includes measuring each battery cell charge and producing corrective charging feedback in a control loop that causes a discharge of individual battery cells to match the charge on other cells.

US2009/0087722 to Sakabe et al. (“Sakabe”) discloses an example of a battery module as described and includes the charge balancing circuitry described. Sakabe discloses a vehicle power supply system battery module comprised of the accumulated battery cell potentials from three distinct but identical battery cell subunits that are hard-wired electrically in series to deliver power from all of the battery cells. Similarly, the Sakabe battery module is charged by current that is delivered to all of the serially connected battery cells. Sakabe's battery module however would be non-functional should any of the Sakabe battery cells or subunits fail.

A vehicle battery system with a backup capability is described in US20120235642 to Mao et al. (“Mao”) wherein a battery module is comprised of subunits having a battery cell and a super-capacitor connectable in parallel as back-up or alternative power. In certain conditions, the battery cell charge may be insufficient to start a vehicle but have enough residual charge to charge a super-capacitor that can discharge very quickly and start a vehicle, or be used when the battery cell temperature is too cold or too hot and unable to deliver sufficient charge to start a car engine. As an example, Mao discloses a number of battery cells connected electrically in series to accumulate a battery module potential that is connected to an alternator to maintain the charge on the battery cells. An ultracapacitor pack comprised of several ultracapacitors electrically in series is then connected in parallel with the battery cells to provide a short and high current for starting the vehicle. Again however, if any of the battery cell(s) or super-capacitor(s) falters, the Mao battery module performance suffers or fails altogether.

Accordingly, there remains a need for improvements in battery module architectures and management strategies and components thereof to facilitate use of lithium-based batteries chemistries in applications where lead-acid based battery use currently dominates.

### SUMMARY OF THE INVENTION

The present disclosure includes improvements to battery architectures or components thereof to enhance the functionality, safety and useful life of batteries. The resulting battery architecture and components facilitates the use and effective management of battery chemistries, such as Lithium, in battery modules intended as substitutes for lead-acid based battery modules.

Aspects of the disclosed invention are embodied in a contactor assembly for a battery module that may include a battery housing positive terminal and a battery housing negative terminal, at least one battery cell having a positive battery cell terminal, and a battery control system with a processor located on a circuit board. The contactor will be located in a contactor housing separated from the circuit board and have a contactor control terminal attachable to the processor, a contactor first terminal that extends through the contactor housing and is attachable to the battery housing positive terminal, and a contactor second terminal that extends through the contactor housing and is attachable to the positive battery cell terminal. A switch with a switch first terminal and a switch second terminal, and a switch control input is included in the contactor assembly. The switch first terminal and the switch second terminal are connected to the contactor first terminal and the contactor second terminal, respectively, and the switch control input coupled to the contactor control terminal and is capable being biased to allow or prohibit current flow between the contactor first terminal and the contactor second terminal. The contactor housing may comprise a thermo-conductive, electrically non-conductive, encapsulation and may be separated from the circuit board by a media selected from air and insulation such that the thermal conductivity between the contactor housing and the circuit board is less than about 1 watt per meter kelvin. The battery module in which the contactor is used may further include a housing wall with a housing wall top portion, and the contactor may be positioned in the housing wall top portion. Further, the contactor may be positioned in the housing wall top portion between the battery housing positive terminal and the battery housing negative terminal.

The contactor first terminal and the contactor second terminal may each respectively comprise a metallic conductor with contactor first terminal interior surface and a contactor second terminal interior surface, respectively, and the contactor first terminal interior surface may be positioned adjacent to and along the contactor second terminal interior surface. Moreover, the contactor first terminal exterior surface and the contactor second terminal exterior surface may each be exposed and positioned alongside each other on the contactor housing exterior. The switch first terminal and the switch second terminal may be mounted on the contactor first terminal interior surface and the contactor second terminal interior surface, respectively.

The switch may comprise a first solid state device and a second solid state device with at least one terminal of each of the first solid state device and the second solid state device coupled together, the switch control terminal may comprise a second of the terminals of each of the first solid state device and the second solid state device coupled together, the switch first terminal may comprise a third terminal of the first solid state device, and the switch second terminal may comprise a third terminal of the second solid state device. The first solid state device and the second solid state device may each be selected from the group consisting of MOSFETs, Bipolar Junction Transistors, JFETs, Insulated Gate Bipolar Junction Transistors or integrated solutions. The first solid state device may comprise a first N-channel FET and the second solid state device comprises a second N-channel FET with the first and second N-channel FET source terminals coupled together. The switch control terminal may comprise the first and second N-channel FET gate terminals, the switch first terminal may comprise the first N-channel FET drain, and the switch second terminal may comprise the second N-channel FET drain.

The switch may also comprise a plurality of first solid state devices each having at least three terminals and a plurality of second solid state devices each having at least at least three terminals. One terminal of each of the plurality of first solid state devices and one terminal of each of the plurality of the second solid state devices may be coupled together, respectively, and the switch control terminal may comprise at least a second terminal of each of the plurality of first solid state devices and at least a second terminal of each of the plurality of second solid state devices. The switch first terminal may comprise at least a third terminal of each of the plurality of first solid state devices, and the switch second terminal may comprise at least a third terminal of each of the plurality of second solid state devices. The plurality of first solid state devices and the plurality of second solid state devices may each be selected from the group consisting of MOSFETs, Bipolar Junction Transistors, JFETs, Insulated Gate Bipolar Junction Transistors or integrated solutions. Or, the plurality of first solid state devices may be a plurality of first N-channel FETs coupled electrically in parallel and the plurality of second solid state devices may be a plurality of second N-channel FETs coupled electrically in parallel The switch control terminal may comprise the gate terminals of the plurality of first N-channel FET gates and the plurality of second N-channel FET gates, and the switch first terminal may comprise the plurality of the first N-channel FET drains, and the switch second terminal may comprise the plurality of the second N-channel FET drains.

The contactor first terminal and the contactor second terminal may each comprise a metallic conductor and the contactor first terminal has a contactor first terminal interior surface of which a portion comprises a switch terminal mounting surface, and the contactor second terminal has a contactor second terminal interior surface of which a portion comprises a switch terminal mounting surface. The switch may comprise a plurality of first solid state devices and a plurality of second solid state devices having at least one terminal of each of the plurality of first solid state devices and each of the plurality of the second solid state devices coupled together, and the switch control terminal may comprise one of the terminals of each of the plurality of first solid state devices and of each of the plurality of second solid state devices. The switch first terminal may comprise a terminal of each of the plurality of the first solid state devices, and the switch second terminal may comprise a terminal of each of the plurality of second solid state devices. The switch first terminal may be mounted on the switch terminal mounting surface of the contactor first terminal interior surface at a position adjacent to the switch second terminal that is mounted on the switch terminal mounting surface of the contactor second terminal interior surface. Further, the plurality of first solid state devices may comprise a plurality of first N-channel FETs and the plurality of second solid state devices may comprise a plurality of second N-channel FETs. The switch control terminal may comprise both of the plurality of first N-channel FET gates and the plurality of second N-channel FET gates, and the switch first terminal may comprise the plurality of the first N-channel FET drains, and the switch second terminal may comprise the plurality of the second N-channel FET drains, and the plurality of the first N-channel FET drains may be mounted on the contactor first terminal interior surface and the plurality of the second N-channel FET drains may be mounted on the contactor second terminal interior surface. Moreover, the contactor housing may be substantially rectangular, and the contactor first terminal interior surface may be oriented substantially parallel to the contactor second terminal interior surface.

Aspects of the invention may also be implemented in a contactor for a battery module that includes a battery housing, a battery housing terminal, at least one battery cell, and a battery control system with a processor located on a circuit board. The contactor may have a contactor housing separated from the circuit board by a media selected from air and a thermal insulator and may have a contactor control terminal that extends through the contactor housing and is coupled to the processor, a contactor first terminal comprising a first metallic conductor that extends through the contactor housing and is coupled to the battery housing terminal, and a contactor second terminal comprising a second metallic conductor that extends through the contactor housing and is coupled to the at least one battery cell. The contactor includes a switch with a switch first terminal and a switch second terminal, and a switch control input. The switch first terminal may be mounted on the first metallic conductor and the switch second terminal may be mounted on the second metallic conductor, and the switch control input may be coupled to the contactor control terminal. The switch control input is controllable to allow or prohibit current flow between the contactor first terminal and the contactor second terminal. The switch may comprise a first solid state device and a second solid state device. The first solid state device and the second solid state device may each have at least three terminals with at least a first terminal of the first solid state device and at least a first terminal of the second solid state device coupled together. The switch control input comprises at least a second of the terminals of the first solid state device and at least a second of the terminals the second solid state device, and the switch first terminal comprises at least a third terminal of the first solid state device, and the switch second terminal comprises at least a third terminal of the second solid state device.

The contactor as described allows management of the battery module by allowing or prohibiting current flow to or from the battery based on control of the contractor control terminal and protects against exposing sensitive electronic components to the heat associated with current and power necessary for engine starts or battery module charging.

### BRIEF DESCRIPTION OF THE DRAWINGS

FIG. 1 illustrates a battery module 100 incorporating aspects of the present disclosure;

FIG. 2 illustrates an aggregate battery module 200 comprising a plurality of battery modules 100, wherein a first subset of battery modules 100 are electrically coupled in parallel to each other, and second subset of battery modules 100 are electrically coupled in parallel to each other, a third subset of battery modules 100 are electrically coupled in parallel to each other, the first subset of battery modules coupled in series with the second subset of battery modules, and the third subset of battery modules connected in series with the second subset of battery modules;

FIG. 3 shows a block diagram of the bi-directional current sensor 300 that includes a current-sense element (e.g. a current-sense resister 320) and a current-to-voltage converter 310 with an analog output 350, a digital output 360 and a digital input;

FIG. 4 illustrates the change in battery module 100 voltage over time due to a start event of an internal combustion engine.

FIG. 5 illustrates an exploded perspective view of the battery module 100;

FIG. 6 illustrates a perspective view of the housing wall top portion 10 and the contactor 140 and the circuit board 82 located therein;

FIG. 7A illustrates a top view of the contactor 140 and illustrates the location of the switch components on the contactor first terminal interior surface 145 and the contactor second terminal interior surfaces 147 and the positioning of the solid state devices, 208 and 210, in the contactor second terminal interior surfaces 147 and the leads of the solid state devices in lead troughs or recesses;

FIG. 7B illustrates a top view of the contactor 140 interior without switch components and illustrating the positioning of the contactor second terminal interior surfaces 147 and the lead recesses;

FIG. 8 illustrates a rear view of the contactor housing 142 showing routing and location of the contactor first terminal exterior surface 148 and the contactor second terminal exterior surface 149;

FIG. 9A illustrates a switch showing the connection between the first and second N-channel FET gate terminals, 208B and 210B, connection of the first and second N-channel FET source terminals, 208A and 210A, connection or use of the first N-channel FET drain 208C to the switch first terminal 202 and connection or use of the second N-channel FET drain 210C; and

FIG. 9B illustrates a plurality of first N-channel FETs 208 coupled electrically in parallel and a plurality of second N-channel FETs 210 coupled electrically in parallel, respectively to implement a preferred switch.

### DESCRIPTION OF PREFERRED EMBODIMENTS

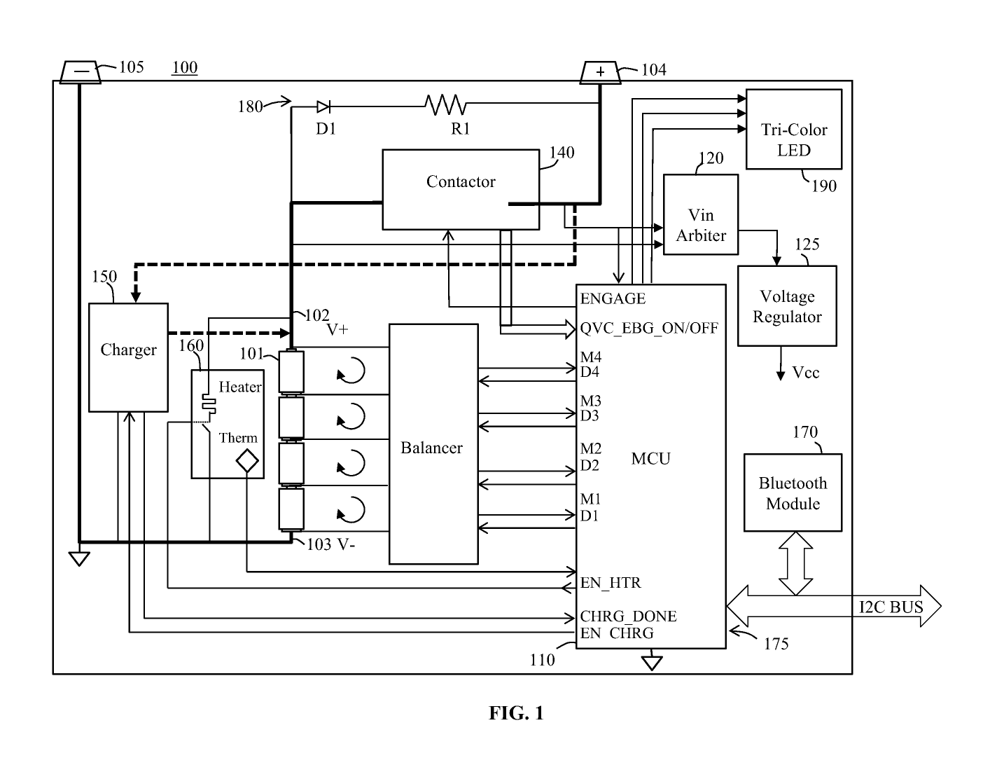

A block diagram of a battery module 100 implementing features of the invention is illustrated in FIGS. 1-3. The battery module 100 embodiment comprises a physically sealed battery based power source including a plurality of Lithium based battery cells 101 operatively coupled to subsystems having distinct functions that operate together to provide safe and reliable power from the battery module 100. See FIG. 1. The battery module 100 is enclosed within a substantially rectangular plastic battery housing and power from the battery module 100 is accessed through a positive battery terminal 104 and a negative battery terminal 105 that each penetrate and conduct electrical current to and from the battery module 100.

FIG. 1 illustrates an application of the invention wherein the battery cells 101 are coupled electrically to each other in series or “stacked” to accumulate or sum the individual battery cell voltages and create the accumulated battery module voltage 102 that is equivalent to the sum of each of the battery cell 101 minus small power losses from the individual battery cell terminals or any conductive connecters between or leading to and from the first and last battery cells 101. Balancing of the voltages on the battery cells 101 is accomplished using the battery cell balancer 130 and a microcontroller 110 that is located on a circuit board 82.

Battery cell 101 balancing comprises measurement, comparison and controlled discharge of selected battery cells 101 to closely balance or equalize the charges on each battery cell 101. Measurement of each battery cell 101 may be accomplished by coupling conductive voltage sensing inputs of a battery cell balancer 130 to the terminals of each battery cell 101 and controlling active components in the battery cell balancer 130 to correctively discharge any single battery cell 101 that has a sensed voltage greater than another battery cell 101 or another reference voltage provided to or within the balancer 130. Accordingly, the balancer 130 comprises a plurality of conductive connections that are respectively coupled to the positive and negative terminals of the individual battery cells 101 and allow a flow of discharge current from each battery cell 101. The illustrated battery cell balancer 130 is implemented with a plurality of analog-to-digital (A/D) converters with the inputs of each A/D converter coupled to one of the terminals of each battery cell 101. See FIG. 1. In the illustrated battery module 110 the inputs of each A/D converter comprise a first input and a second input that are connected to the negative terminal and positive terminal of each battery cell 101, respectively, to enable sampling or measurement of the voltage existing on each battery cell 101. The battery cell balancer 130 is coupled to a microcontroller 110 that compares the voltages on each of the battery cells 101 and directs corrective discharge feedback to the balancer 130 according to programming within the microcontroller 110.

Battery cell 101 voltages sampled from the battery cell balancer 130 are coupled to the microcontroller 110 for comparison and subsequent correction if necessary. Particularly, the outputs of the A/D converters in the cell balancer 130 are each coupled to an input/output port on the microcontroller 110 that is programmed to read the digital outputs from the A/D converters of the cell balancer 130 (i.e. “M4”) into microcontroller memory. The microcontroller is programmed to compare the cell voltages and output corrective discharge feedback (i.e. “D3”) that is coupled to the cell balancer 130 and controls the operation of a discharging circuit that may include active circuitry configured to discharge any individual battery cell 101 in the stack having excessive charge or exceeding a reference voltage. As one example, the corrective discharge feedback is applied to the gate of a Field Effect Transistor (FET) wherein the drain and source are coupled across the positive and negative terminals of the battery cell, respectively and the corrective discharge feedback causes the FET to drain current from the battery cell that requires discharging. Electrical isolation of the cell balancer 130 discharge circuitry may be provided by opto-couplers coupled between the discharge feedback from the microcontroller 110 and the cell balancer 130 discharge circuitry.

A thermistor and heater 160 is positioned in the thermal environment adjacent the battery cells 101 to both measure and affect battery cell 101 temperatures. The heater 160 comprises a resistive heating element that is coupled between the accumulated battery module voltage 102 and system ground. The thermistor (“Therm”) may be coupled to the microcontroller 110 via an analog-to-digital converter to sample current measurements, which may be read-in by the microcontroller 110 to determine the temperature of the thermal environment adjacent the battery cells 101. As one example, the microcontroller 110 programming reads the thermistor measurements into memory and compares the measurements to internal reference values to determine whether the battery cells 101 are too cold to be safely charged and the heater 160 should be turned on to increase the temperature of the battery cell 101 environment. The microcontroller 110 can be programmed to turn on the heater 160 if the ambient temperature is below a threshold temperature (e.g. −10 degrees Celsius). The microcontroller 110 may turn on the heater 160 by closing a switch in the current path of the resistive heating element using a heater enable output (“EN_HTR”). Closing the switch allows current to flow through the resistive heating element and heat the environment adjacent the battery cells 101. Conversely, the microcontroller 110 may disable the heater 160 by opening the switch in the path of the resistive heating element.

A solid-state contactor 140 is electrically coupled in series between the battery cells 101 and the positive battery terminal 104 and has a CLOSED state and an OPEN state. When in the CLOSED state the contactor 140 allows current flow between the accumulated battery cell voltage 102 and the positive battery terminal 104. Conversely, when in the OPEN state the contactor 140 presents an open circuit or near infinite impedance between the accumulated battery cell voltage 102 and the positive battery terminal 104. The contactor 140 is coupled to or combined with a bi-directional current sensing circuit 300 to sense the magnitude and polarity of current flow to and from the battery module 100, which is indicative of engine or battery module 100 operating states and/or state changes.

An example of a bi-directional current sensing circuit 300 is illustrated in FIG. 3 and comprises a bi-directional current sense current-to-voltage converter (“I-V Converter”) 310 that reproduces or amplifies the voltage differential produced by the current flowing through a current sense element (e.g. a current-sense resistor 320) that is electrically coupled in series between the positive battery terminal 104 and the engine cable that supplies power to the engine. The gain of the I-V Converter 310 may be programmably increased or decreased based on input from the microcontroller 110 to accommodate the current-use characteristics of alternate battery applications. The bi-directional current sensing circuit 300 may include an analog output 350 that outputs a proportional representation of the current flowing through the current sense element, which may be coupled to the microcontroller 110 via an analog-to-digital converter to enable measurement and capture of on-going current use data. One or more binary or digital outputs 360 may be coupled to the microcontroller 110 to provide output information that is representative of the current flowing through the current sense element. The illustrated bi-directional current sensing circuit 300 includes a two digit binary data/output that is representative of both the magnitude and polarity of the current flowing through the current sense element.

The contactor 140 has a contactor control terminal 141 that is coupled to a port of the microcontroller 140 (“ENGAGE”) and that is used to cause the contactor 140 to change states (i.e. “OPEN”) and cause an open circuit in the path between the accumulated battery cell voltage 102 and the positive battery cell terminal 104. The OPEN state of the contactor 140 may be useful during programmed management of the battery module 100 or if the battery module 100 is subject to unsafe operating conditions that might damage the battery module 100 components. Unsafe operating conditions that cause the microcontroller 110 to toggle the ENGAGE output and cause an OPEN state of the contactor 140 include threats of both internal and external origin. Examples of internal threats include overcharged or undercharged battery cells 101, one or more failed or faulty battery cells 101, or battery cell 101 temperatures outside specified limits while the engine is running (i.e. “ENGINE_ON”). Each of the threats having internal origins can be detected by the microcontroller 110 programming and eliminated. External threats associated with extreme current magnitudes are detected with the bi-directional current sensing circuit 300.

Over-current conditions created externally to the battery module 100 can be detected and terminated before the battery module 100 is damaged or does damage to other engine components. If for example, the positive battery terminal 104 and negative battery terminal 105 are shorted (or during any other sustained over-current condition), a very large and sustained battery current will result in a sustained relatively large magnitude of current through the current-sense resistor 320 that the bi-directional current sensing circuit 300 will convey to the microcontroller 110 (“OVC”). The microcontroller 110 will immediately toggle the ENGAGE output to cause an OPEN state of the contactor 140 and end the short-circuit (or over-current condition). Similarly, a substantial change in battery current may indicate a significant change in the load impedance that can be detected by the microcontroller 110 and stored in memory or reported to the engine computer or transmitted to remote receivers. Finally, the contactor 140 OPEN state condition can also be selected based upon receipt of interrupts or other commands that are communicated to the microcontroller 110 from a communication 170 that is able to communicate with one or more remote wired or wireless transceivers.

The bi-directional current sensing circuit 300 may also be used under normal battery module 100 operating conditions to detect battery current consumption and engine operating states and state changes. As an example, the start event of an internal combustion engine as initiated by a starter-motor requires a sudden and relatively large inrush current. If the engine is in the OFF state, the contactor 140 is normally in the CLOSED state to allow battery current to flow from the battery module 100 to power a starter-motor for an engine start event. FIG. 4 illustrates the possible change in battery module voltage, V_{+Bat}, due to an engine start event and followed by an engine stop/off event. Before the engine start event, the battery module 100 produces voltage at the positive battery terminal 104 that is substantially equal to the accumulated battery cell 101 voltages, V_{ACC}. At an engine start event, tsₜₐᵣₜ, the start-current flowing from the battery module 100 will be enough to reduce the battery module voltage to less than a programmable reference threshold voltage, Vₜₕᵣ, that is less than the original accumulated battery cell voltage, V_{ACC}, and preferably less than about seventy percent of the original accumulated battery cell 101 voltage. The microcontroller 110 programming detects each occurrence when the batter terminal 104 voltage decreases to less than the reference threshold voltage, which may be used internally within the microcontroller 110 as an interrupt (e.g. “IGNITION_ON”) or communicated external to the battery module 100 or both.

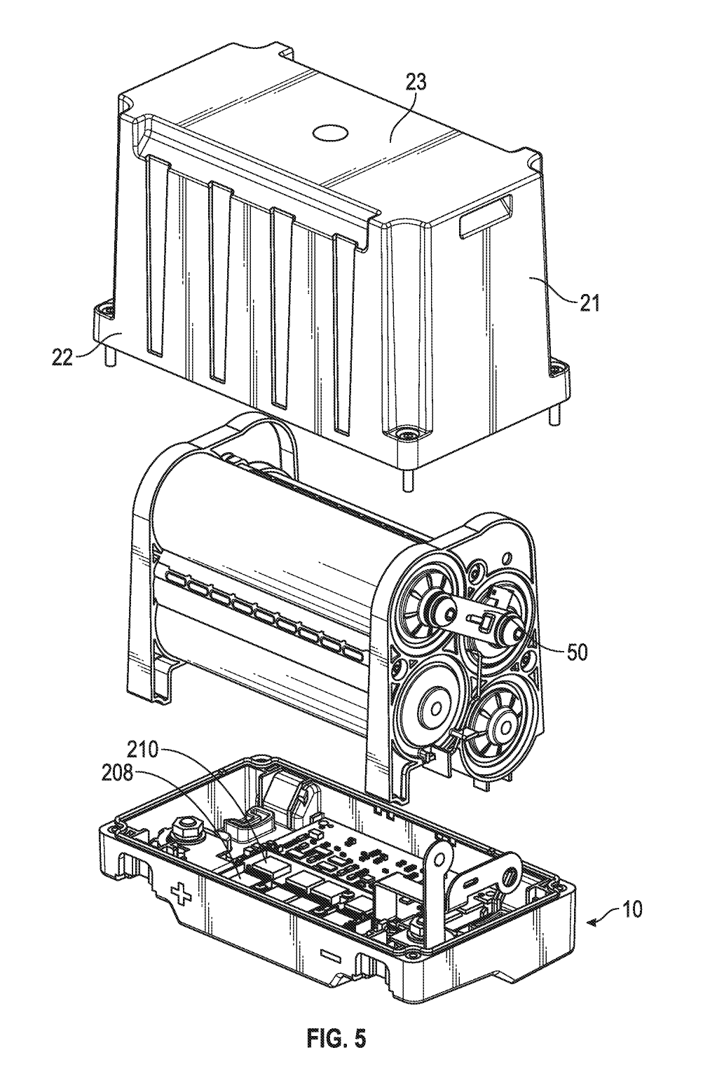

The contactor 140 will conduct approximately 400-500 Amps during vehicle engine start events and may also conduct a lessor but still significant current load while charging the battery module 100 depending on the states of charge of the battery cells 101. The contactor 140 is thus optimized for thermal performance and also thermally isolated from the circuit board 82 that contains the microcontroller 110 and other battery module architecture components that could be damaged by heat dissipated from the contactor 140 and contactor housing 142 during engine starts or battery charging. FIG. 5 for example illustrates the housing wall top portion 10 that includes a circuit board 82, which contains the microcontroller 110 and other battery module architecture components. The contactor 140 however is packaged or housed separately apart from the circuit board 82 within a separate contactor housing 142 to reduce the exposure of the microcontroller 110 and the other electronic components to the heat dissipated by the contactor 140. An air-gap between the contactor housing 142 and the circuit board 82 isolates the circuit board 82 from the heat dissipated by the contactor 140. Alternatively, a thermal insulator may also be included between the contactor 140 and circuit board 82 to shield the circuit board 82 from heat. If used, a thermal insulator should have a thermal conductivity of less than 1 watt per meter kelvin and will preferably have the thermal conductivity of an air-gap or less i.e. about 0.024 watts per meter kelvin. In most applications, the thermal conductivity between the contactor 140 and circuit board 82 should be no greater than about 0.25 watts per meter kelvin.

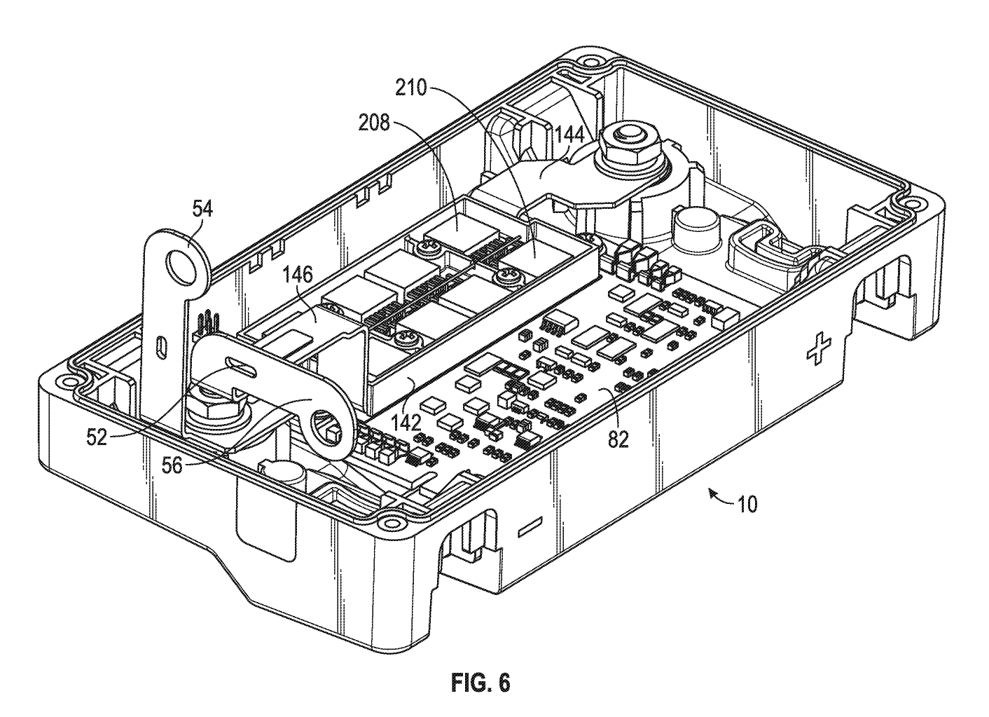

The contactor 140 may be positioned in the housing wall top portion 10 between the battery housing positive terminal 104 and the battery housing negative terminal 105 and the contactor housing 142 shape may be substantially rectangular with a contactor housing length and a contactor housing width that are each oriented along the length and width of the housing wall top portion 10, respectively. See FIGS. 5 and 6. Moreover, the contactor housing 142 may comprise any of a variety of solid state electronic packaging materials but a preferred packaging material comprises a thermo-conductive, electrically non-conductive, encapsulation. A contactor first terminal 144, a contactor second terminal 146, and the contactor control terminal 141 each extend through the contactor housing 142 and are attachable or coupled to the battery housing positive terminal 104, the positive terminal of the at least one battery cell 101, and the microcontroller 110, respectively. The contactor housing 142 may be attached to, or positioned adjacent to, the housing wall top portion 10 such as buy fastening hardware that attaches the contactor first terminal 144 and contactor second terminal 146 to the battery housing positive terminal 104 and the at least one battery cell 101, respectively.

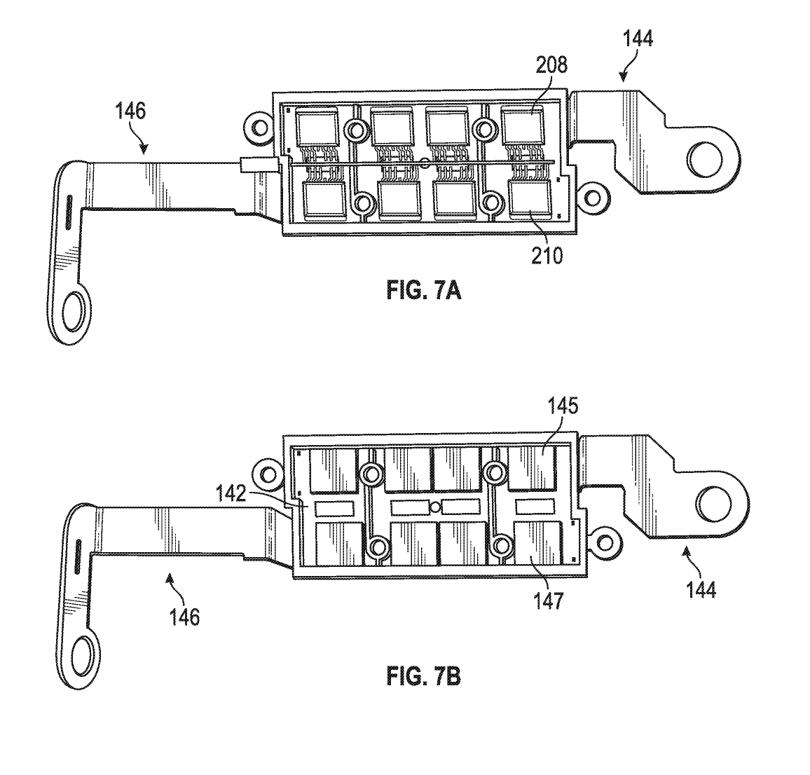

The contactor first terminal 144 and the contactor second terminal 146 may each respectively comprise a metallic conductor and have a contactor first terminal interior surface 145 and contactor second terminal interior surfaces 147, respectively. The contactor terminals, 144 and 146, and the interior surfaces thereof, 145 and 147, each preferably comprise metallic conductors that are at least as rigid as 16 gauge wire but will preferably have an elastic deformation at least 500% greater than the elastic deformation of a 16 gauge wire. As one example, the illustrated solid metallic conductors for each contactor terminal, 144 and 146, may comprise a rectangular metallic bus bar having a width of between about 0.25 and about 2 cm but preferably about 1 cm and a thickness of between about 0.5 and 2 mm but preferably about 2 cm. Moreover, the contactor bus bars may be constructed, bent, or configured along the length to have one or more corners or angles to avoid other components and/or to position the contactor bus bars for attachment to the battery housing positive terminal 104 or the at least one battery cell 101, respectively. As illustrated in FIGS. 7A & 7B, the bus bar of the contactor first terminal 144 originates at a first end of the contactor housing 142 and extends along the outside length thereof and couples to the battery housing positive terminal 104. An aperture in the bus bar receives a bolt extending from the battery housing positive terminal 104, which is secured with a nut. Similarly, the bus bar of the contactor second terminal 146 originates at a second end of the contactor housing 142, and extends along the outside length thereof, and couples to the at least one battery cell 101 terminal via an aperture in the bus bar that receives a screw. The contactor first terminal interior surface 145 and contactor second terminal interior surfaces 147 may be laterally adjacently positioned within the contactor housing 142, which includes positioning variations where the surfaces, 145 and 147, have adjacent surfaces spaced apart within the contactor housing 142 sufficiently close to both enable the components of the switch and the terminals thereof to be in close proximity and also position at least certain of the switch components in electrical and thermal contact or communication with the contactor 140 and with optional additional heat-sinks or heat-spreaders attachable thereto.

The switch includes a switch first terminal 202 a switch second terminal 204, and a switch control input 206. The switch first terminal 202 and the switch second terminal 204 are connected to the contactor first terminal interior surface 145 and the contactor second terminal interior surfaces 147, respectively, and the switch control input 206 is coupled to the contactor control terminal 141. Thermal communication between the switch and the contactor 140 generally indicates a thermal conductivity sufficiently low to ensure that the heat generated by the switch is conducted away from the contactor 140 by using the contactor first terminal 144 to conduct heat away from the contactor 140 to the battery housing positive terminal 104 or to one or more heat-sinks or heat-spreaders mounted to the contactor housing 142. The switch allows or prohibits current flow between a switch first terminal 202 and a switch second terminal 204 as controlled by the switch control input 206 that is coupled to the microcontroller 110 through the contactor control terminal 141. The switch allows bi-directional current flow to enable the battery module 100 to source current during engine start events or sink charging current. Further, in a preferred switch design, the direction of current flow (i.e. whether current flows from the switch first terminal 202 to the switch second terminal 204 (or vice versa)) depends on the voltage differential between the switch first terminal 202 and the switch second terminal 204 and whether current flow is enabled by the switch control input 206, only. If current flow is enabled, a positive voltage differential between the switch first terminal 202 and the switch second terminal 204 results in current flow from the switch first terminal 202 to the switch second terminal 204, and a negative voltage differential between the switch first terminal 202 and the switch second terminal 204 results in current flow to the switch first terminal 202 from the switch second terminal 204.

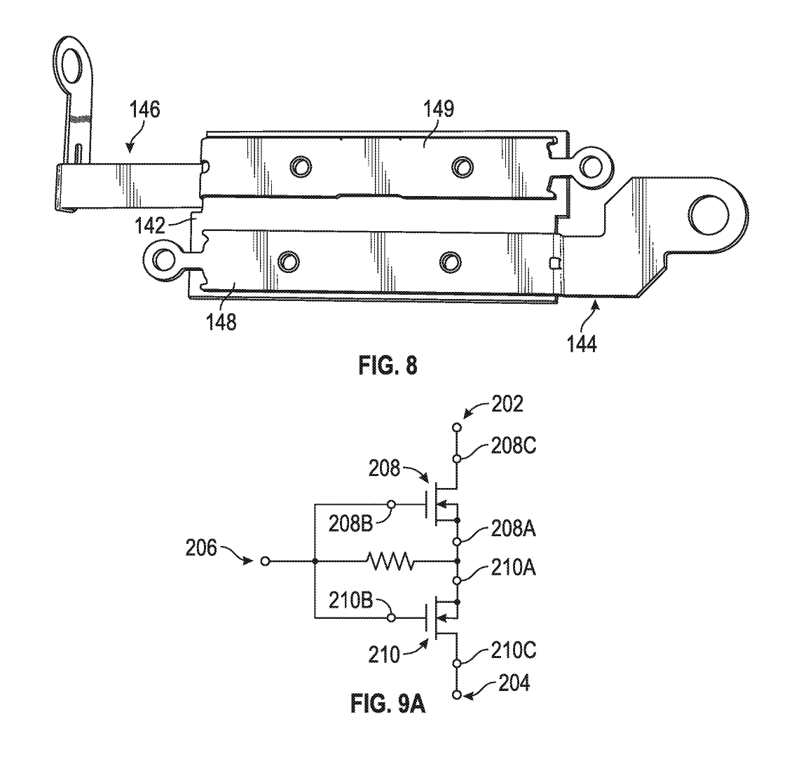

A preferred switch with bi-directional current capabilities may comprise first and second solid state devices (or plurality of first and second solid state devices) that are each respectively coupled to or mounted on, such as by a thermal adhesive or mechanical mounting, to the laterally adjacently positioned contactor first and second terminal interior surfaces, 145 and 147, which are at least partially aligned and oppositely oriented so the respective terminals of the first and second solid state devices of the switch are separated by the electrically non-conductive gap or space between the contactor first and second terminal interior surfaces, 145 and 147. See FIG. 7A. Additionally, the contactor housing 142 may have lead troughs or recesses for positioned placement and electrical connection of certain leads of the solid state devices. A typical distance between the contactor first and second terminal interior surfaces, 145 and 147, will usually be between about 0.05 cm and 2 cm, the preferred distance or gap is preferably about 0.5 cm. Moreover, because the contactor housing 142 may comprise a molded construction or assembly, the gap or space between the contactor first and second terminal interior surfaces, 145 and 147, may comprise material of the molded thermo-conductive encapsulate used to form the contactor housing 142. Finally, the contactor first and second terminal exterior surfaces 148 and 149, are each exposed on an outside wall of the contactor housing 142 exterior and to which external heat-sinks are be attachable. See FIG. 8.

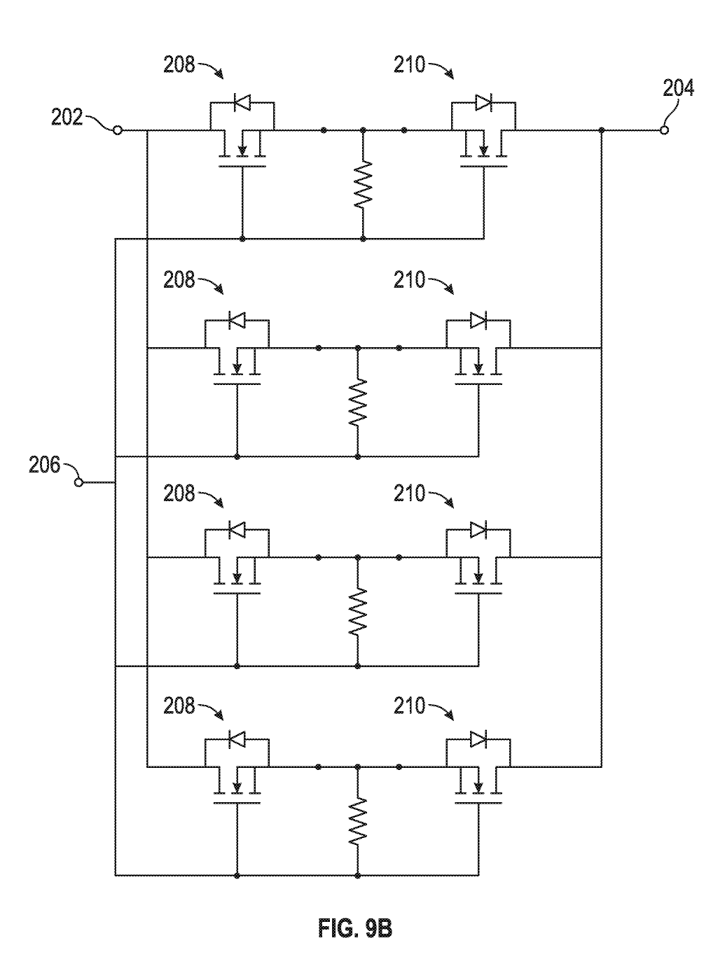

An embodiment of the switch having bi-directional current capabilities may be comprised of at least two solid state devices having at least three terminals each. The first solid state device and the second solid state device each have at least one terminal of the first three-terminal solid state device and the second three-terminal solid state device coupled together. The switch control input 206 comprises at least a second of the terminals of the first solid state device and at least a second of the terminals of the second solid state device. The switch first terminal 202 comprises at least a third terminal of the first solid state device, and the switch second terminal 204 comprises at least a third terminal of the second solid state device. Moreover, the switch first terminal 202 may be mounted directly on or to the contactor first terminal interior surface 145 and the switch second terminal 204 may be mounted directly on or to the contactor second terminal interior surfaces 147. FIG. 9A illustrates a schematic of this embodiment and comprises use of a first N-channel FET 208 and a second N-channel FET 210 as the first and second solid state devices. The first and second N-channel FET source terminals, 208A and 210A, are coupled together, and the switch control terminal or input 206 comprises the first and second N-channel FET gate terminals, 208B and 210B. The switch first terminal 202 comprises the first N-channel FET drain 208C, the switch second terminal 204 comprises the second N-channel FET drain 210C. A resistor is coupled between the gate terminals, 208B and 210B, and the source terminals, 208A and 210A.

Switch operation depends on the voltage applied to the switch control input 206 and the voltage differential between the first and second switch terminals, 202 and 204, respectively. If a sufficient biasing voltage is applied at the switch control input 206 (e.g. greater than the MOSFET threshold voltage), a positive voltage differential between the switch first terminal 202 and the switch second terminal 204 results in current flow from the switch first terminal 202 to the switch second terminal 204. Or, and again if a sufficient biasing voltage is applied at the switch control input 206, a negative voltage differential between the switch first terminal 202 and the switch second terminal 204 results in current flow to the switch first terminal 202 from the switch second terminal 204. During the described operation, the first N-channel FET 208 operates in the active region, the second N-channel FET 210 operates in cut-off, and the body diode of the second N-channel FET 210 allows reverse drain current (i.e. freewheeling current), for positive voltage differentials between the switch first terminal 202 and the switch second terminal 204. Alternatively, the second N-channel FET 210 operates in the active region, the first N-channel FET 208 is cut-off, and the body diode of the first N-channel FET 208 allows reverse drain current for negative voltage differentials between the switch first terminal 202 and the switch second terminal 204. If on the other hand, an insufficient biasing voltage is applied at the switch control input 206 (i.e. less than the threshold voltage of the MOSFET), the first N-channel FET 208 or the second N-channel FET 210 will be in cut-off mode and current flow in either direction through the switch terminals, 202 and 204, is prohibited irrespective of the magnitude or polarity of the voltage differential between the switch first terminal 202 and the switch second terminal 204. Finally, whereas use of N-channel FETs is preferred, it would be within the knowledge of one of ordinary skill to alter the preferred design to use P-channel FETs, other power transistors, such as Bipolar Junction Transistors, JFETs, Insulated Gate Bipolar Junction Transistors or integrated solutions with equivalent capabilities or functions given the operation described herein.

For greater current loads, a plurality of solid state devices may be connected and controlled in parallel to divide the current load of the switch between several devices. In such embodiments, the switch generally comprises a plurality of first solid state devices and a plurality of second solid state devices, each having at least three terminals with at least a first terminal of each of the plurality of first solid state devices and at least a first terminal of each of the second plurality of solid state devices coupled together, respectively. The switch control input 206 comprises at least a second of the terminals of each of the plurality of first solid state devices and at least a second of the terminals of each of the plurality of second solid state devices coupled together. The switch first terminal 202 comprises at least a third terminal of each of the plurality of the first solid state devices coupled together, and the switch second terminal 204 comprises at least a third terminal of each of the plurality of second solid state devices coupled together. FIG. 9B illustrates a schematic of a preferred implementation of the embodiment.

The preferred implementation includes use of a plurality of first N-Channel FETs 208 and a plurality of second N-Channel FETs 210 as the plurality of first and the plurality of second solid state devices coupled together to operate and be controlled as a single solid state pair as illustrated in FIG. 9A, but divide the contactor 140 current between a plurality of solid state pairs. Thus, the plurality of first and second N-channel FET gate terminals, 208B and 210B, are all coupled electrically together and comprises the switch control terminal or input 206. A plurality of carbon composition resistors (“R1, R2, R3, R4”) are each coupled between each of the gate terminals, 208B and 210B, and the source terminals, 208A and 210A improve the matching of the turn on and turn off time located adjacent the FETs to minimize ringing. The plurality of first N-channel FET drain 208C drain terminals are all coupled electrically together, and the plurality of the second N-channel FET drains 210C are coupled electrically together, respectively, as illustrated in FIG. 9B and the switch first terminal 202 comprises the plurality of the first N-channel FET drains 208C, and the switch second terminal 204 comprises the plurality of the second N-channel FET drains 210C. Finally, each of the plurality of first N-channel FET source terminals 208A is coupled to one of the plurality of second N-channel FET source terminals 210A, respectively. Or alternatively, all of the first N-channel FET source terminals 208A are coupled to all of the second N-channel FET source terminals 210A. Again, because the contactor first terminal interior surface 145 and the contactor second terminal interior surfaces 147 may be laterally adjacently positioned within the contactor housing 142, one of each of the plurality of first N-Channel FETs 208 is positioned proximate and opposite one of each of the plurality of second N-Channel FETs 210 to facilitate proximately opposite connections between the pluralities of first and second N-channel FETs, 208 and 210, such as the pluralities of first and second N-channel FET source terminals, 208A and 210A, as illustrated. FIG. 7A for example illustrates partial alignment and opposite orientation of pins 2-7 of each of the plurality of the first N-channel FETs 208 with pins 2-7 of one of the plurality of second N-channel FETs 210. Moreover, the aligned pins 2-7 of each pair of partially aligned and oppositely oriented first N-channel FETs 208 and second N-channel FETs 210 are positioned over or within a trough or recess that may include an electrically conductive material that electrically connects the pins together. Further, the plurality of first N-channel FET drains 208C and the plurality of second N-channel FET drains 210C are each respectively mountable on and in electrical contact and thermal communication with the contactor first terminal 144 and the contactor second terminal 146, respectively, and also in thermal communication or contact with optional additional heat-sinks or heat-spreaders attachable to the contactor first terminal exterior surface 148 and/or the contactor second terminal exterior surface 149 at the contactor housing 142 exterior.

To facilitate assembly of the contactor 140, spacers or separators molded or constructed within the contactor housing 142 interior may delineate portions of the contactor first and second terminal interior surfaces, 145 and 147, as switch terminal mounting surfaces for the plurality of the second N-channel FET drains 210C and a switch terminal mounting surfaces for the plurality of the second N-channel FET drains 210C. See FIG. 7B. Further, such portions on the respective contactor first and second terminal interior surfaces, 145 and 147, may be offset to align certain terminals of the plurality of first N-channel FETs 208 and plurality of second N-channel FETs 210 such as the pluralities of first and second N-channel FET source terminals, 208A and 210A, as described earlier. The delineated portions preferably have dimensions and shape to receive the heat-spreader, tab, or flange of the solid state devices and align the solid state devices as explained herein and as illustrated in the drawings. Moreover, the lead recesses or troughs are positioned and sized for electrical connection of the first and second N-channel FET source terminals, 208A and 210A. Again, the contactor first terminal 144 and the contactor second terminal 146 each respectively comprise a solid metallic conductor such as a bus bar and the switch terminal mounting surfaces on each bus bar comprise a portion or portions of the bus bar surfaces that are interior to the contactor housing 142 and on which the plurality of first N-channel FET drains 208C and second N-channel FET drains 210C can be mounted such as by adhesive or mechanical mounting means. Laterally adjacently positioned contactor first or second terminal interior surfaces, 145 and 147, respectively, enables efficient connection of the plurality of first N-channel FETs 208 and the plurality of second N-channel FETs 210. As an example, the plurality of first N-channel FETs 208 and second N-channel FETs 210 may each comprise an IPB180NO3S4L, which is an n-channel enhancement mode seven-pin MOSFET encapsulated within plastic or ceramic that includes a base plate or flange or tab that is both the N-FET drain terminal and a heat-spreader that can be thermally coupled to a metallic conductor such as the bus bars that function as the contactor first terminal 144 and contactor second terminal 146, respectively. In such implementations, the plurality of first N-channel FET drains 208C and the plurality of second N-channel FET drains 210C are mounted on the bus bars such as by a thermally conductive interface adhesive or mechanical fastening or both.

After engine start and under normal operating conditions, the battery module 100 will provide current to the engine electrical system until a time t_{charge}, (exaggerated in the drawing) when the alternator voltage applied to the positive battery terminal 104 just exceeds the accumulated battery cell voltage, V_{ACC}, and begins to charge the battery cells 101 by current flowing from the engine alternator, through the positive battery terminal 104 and contactor 140, to the battery cells 101. The microcontroller 110 programming may detect each occurrence when the battery terminal voltage 104 returns to or exceeds the original accumulated battery cell 101 voltage, V_{ACC}, which occurrences may be used internally within the microcontroller 110 as interrupt (e.g. “ENGINE_ON”) or communicated external to the battery module 100 or both. Finally, the engine entering an off state, at t_{off}, results with the voltage at the positive battery terminal 104 decreasing or returning to substantially the same voltage as the original accumulated battery cell 101 voltage, V_{ACC}, and may correspond to an engine off (“ENGINE_OFF”) signal/interrupt for the microcontroller 110.

Charging of the battery cells 101 by the manner described above is allowed provided that the current flowing from the positive battery terminal 104 to the battery cells 101 remains less than a programmed reference current chosen to ensure that a safe charging current is applied to the battery cells 101. Under certain conditions however, the current flowing from the positive battery terminal 104 to the battery cells 101 may exceed the programmed reference current and charging of the battery cells 101 is provided by the internal battery cell charger 150.

The battery cell charger 150 is electrically coupled 151 to the positive battery terminal 104 to provide controlled charge of the battery cells 110. The battery cell charger 150 has a charging output source 150a that is coupled to the battery cell 101 stack and that may source a safe charging current to the battery cells 101 as controlled by the microcontroller 110 programming. The charger 150 is coupled to the microcontroller 110 (i.e. at “EN-CHRG”) and enabled or disabled (“CHRG_DONE”) by the microcontroller 110 based on whether the battery cells 101 require charging or have finished charging. In one example the microcontroller 110 directs the charger 150 to charge the battery cells 110 if charging current though the contactor 140 exceeds a safe level of charging current, or the voltage at the positive battery terminal 104 is greater than the accumulated battery cell voltage 102, or if the accumulated battery cell voltage 102 is below a reference voltage established by programing in the microcontroller 110.

A low power current path 180 (coupled electrically in parallel to the contactor 140) from the accumulated battery module voltage 102 to the positive battery terminal 104 allows power from the battery module 100 to power external components such as vehicle engine computers and the like. An exemplary low current path 180 comprises a diode (“D1”) and resistor (“R1”) coupled electrically in series from the accumulated battery module voltage 102 to the positive battery terminal 104 i.e. with the diode anode coupled to the accumulated battery module voltage 102, the diode cathode coupled to a first end of the resistor, and the other end of the resistor coupled to the positive battery terminal 104.

A voltage source multiplexer Vin Arbiter 120 powers a voltage regulator 125 that supplies internal power to the microcontroller 110. The Vin Arbiter 120 multiplexes power from the positive battery terminal 104 and accumulated battery module voltage 102 depending upon which voltage potential is greater. Thus, for example when the engine is in the ENGINE_ON state the Vin Arbiter 120 may select and power the voltage regulator 125 from the greater voltage potential of either the positive battery terminal 104 or from accumulated battery module voltage 102. And when the engine is in the ENGINE_OFF state the Vin Arbiter 120 selects and powers the voltage regulator 125 from the accumulated battery module voltage 102.

A communications link to and from the battery is provided via a wired or wireless link and facilitates communications with other battery communication links in other battery modules 100 or with other external or remote devices. For example, the microcontroller 110 can be programmed to communicate battery module 100 status information to engine computers or other external devices. Battery module 100 status information may include but is not limited to minimum battery cell voltage, current consumption, error messages, or occurrences of over-current or over-voltage conditions. The communications link is also useful to establish and maintain communications between battery modules 101 that are deployed in parallel or series to augment power requirements or accomplish battery module power 100 redundancies. As illustrated the communications link can be a wired 175 (e.g. I2C® bus) or a wireless 170 (e.g. Bluetooth®) technology.

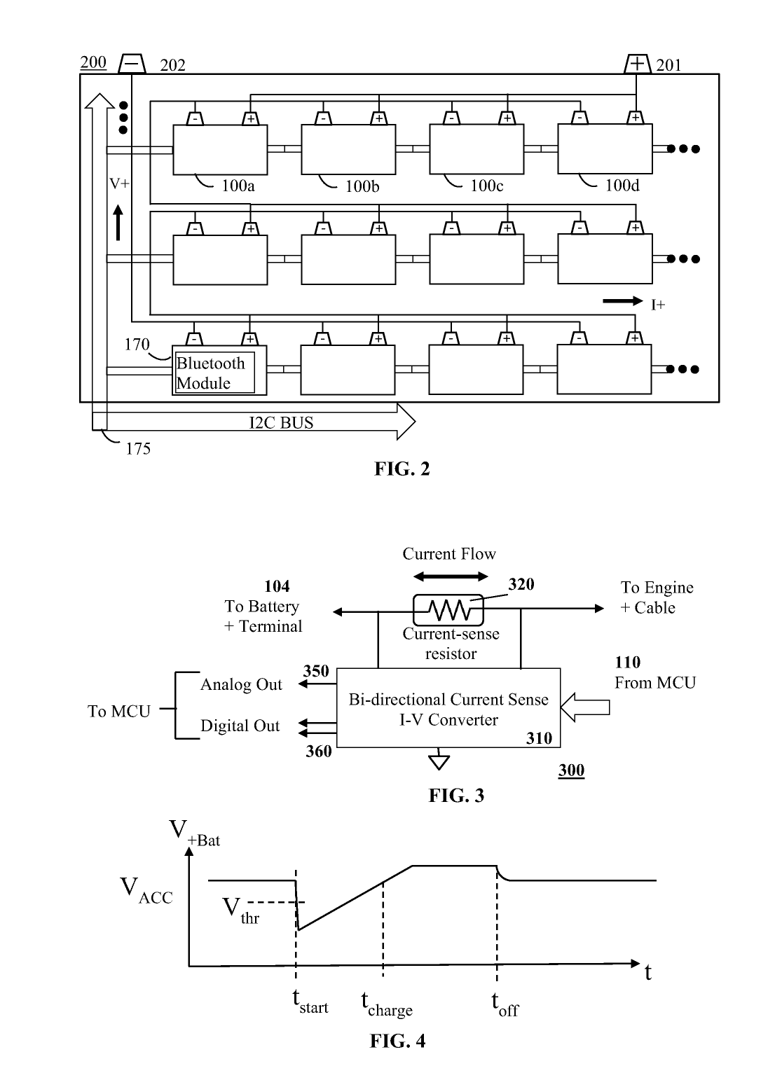

FIG. 2 for example illustrates an aggregated battery module 200 having a positive battery terminal 201 and a negative battery terminal 202 but is actually comprised of a plurality of self-contained and independently-internally managed battery modules 100 connected to achieve power objectives beyond that of a single battery module 100. In particular the aggregated battery module 200 comprises three subsets of battery modules 100 (i.e. the vertical stack of the three rows of battery modules 100 to accumulate “V+”), wherein each of subsets of battery modules 100 (e.g. have been coupled electrically in parallel to sum the battery module 100 current capabilities (i.e. the horizontal rows of four battery modules 100 to accumulate “I+”); and wherein the each of the three subsets of battery modules 100 are coupled in series to sum the voltage capabilities.

The problems normally associated with connecting batteries are addressed by monitoring and managing each of the battery modules 100 connected in parallel using the communications link. As an example, bottom row of battery modules 100 in FIG. 2 includes a master battery module 100a that monitors and manages operations battery modules 100b, 100c, 100d . . . that are electrically connected in parallel with the master battery module 100a. In operation, the master battery module 100a polls each of the other battery modules 100b, 100c, and 100d . . . for information regarding the status of each of the other battery modules 100b, 100c, 100d . . . . and in particular the voltage of each individual battery cell in each of the other battery modules 100b, 100c, and 100d . . . and issues commands via the communications link to each of the microcontrollers 110b, 110c, 110d . . . . , to balance each of the individual battery cell voltages to the lowest battery cell 101 voltage or alternatively, a common battery cell reference voltage as established by the master battery module 100a.

The communications links also enables battery management strategies that promote prolonged battery module 100 life or that facilitate redundant power. The master battery module 100a may run a program that controls the operation of battery modules 100b, 100c, and 100d, . . . One preferred management strategy is to disconnect each battery module 100 for a time interval and allow the other batteries to supply aggregate power. Thus, in the example if there are N batteries in the aggregate battery module 200 the master battery module 100a will command one of the other battery modules 100b, 100c, and 100d, . . . to open its contactor 140b, 140c, or 140d, . . . respectively so that N-1 battery modules 100 are supplying power from the aggregate battery module 200 at any given time. Alternatively, the master battery module 100a may command more than one of the other battery modules 100b, 100c, and 100d, . . . to open its contactor 140b, 140c, or 140d, . . . respectively so that fewer than N-1 battery modules 100b, 100c, and 100d, . . . are supplying power from the aggregate battery module 200 at any given time.

Finally, the battery module 100 includes a visual status indicator such as a multi-color LED 190 that is coupled to a port on the microcontroller 110 that indicates one or more statuses by the intermittent or steady display of several colors lit by the multi-color LED 190. Moreover, an accelerometer can be included to ensure that one or more battery module 100 operations are not initiated if the battery module 100 is not in an upright orientation.

While various embodiments have been described above, it should be understood that they have been presented by way of example only, and not limitation. Thus, the breadth and scope of a preferred embodiment should not be limited by any of the above-described exemplary embodiments, but should be defined only in accordance with the following claims and their equivalents.

1. A contactor assembly for a battery module, the battery module comprised of a battery housing positive terminal and a battery housing negative terminal, at least one battery cell having a positive battery cell terminal, and a battery control system with a processor located on a circuit board, the contactor assembly comprising;
a contactor housing separated from the circuit board;
a contactor control terminal attachable to the processor, a contactor first terminal that extends through the contactor housing and is attachable to the battery housing positive terminal, and a contactor second terminal that extends through the contactor housing and is attachable to the positive battery cell terminal; and
a switch with a switch first terminal a switch second terminal, and a switch control input, the switch first terminal and the switch second terminal connected to the contactor first terminal and the contactor second terminal, respectively, and the switch control input coupled to the contactor control terminal;
wherein the switch control input is controlled to allow or prohibit current flow between the at least one battery cell and the battery housing positive terminal.

2. The contactor assembly in claim 1 wherein,
the contactor housing comprises a thermo-conductive, electrically non-conductive, encapsulation.

3. The contactor assembly in claim 1 wherein,
the contactor housing is separated from the circuit board by a media selected from air and insulation.

4. The contactor assembly in claim 3 wherein,
the thermal conductivity between the contactor housing and the circuit board is less than about 1 watt per meter kelvin.

5. The contactor assembly in claim 4 wherein,
the battery module further includes a housing wall with a housing wall top portion and the contactor is positioned in the housing wall top portion.

6. The contactor assembly in claim 5 wherein,
the battery housing positive terminal and the battery housing negative terminal each penetrate the housing wall top portion and the contactor is positioned in the housing wall top portion between the battery housing positive terminal and the battery housing negative terminal.

7. The contactor assembly in claim 1 wherein,
the contactor first terminal and the contactor second terminal each respectively comprise a metallic conductor, the contactor first terminal has a contactor first terminal interior surface, the contactor second terminal has a contactor second terminal interior surface, and the contactor first terminal interior surface is positioned adjacent to and along the contactor second terminal interior surface.

8. The contactor assembly in claim 1 wherein,
the contactor housing has a contactor housing exterior, the contactor first terminal has a contactor first terminal exterior surface, the contactor second terminal has a contactor second terminal exterior surface, and the contactor first terminal exterior surface is exposed with the contactor second terminal exterior surface on the contactor housing exterior.

9. The contactor assembly in claim 7 wherein,
the switch first terminal and the switch second terminal are mounted on the contactor first terminal interior surface and the contactor second terminal interior surface, respectively.

10. The contactor assembly in claim 1 wherein,
the switch includes a first solid state device and a second solid state device with at least one terminal of each of the first solid state device and the second solid state device coupled together, the switch control terminal includes a second of the terminals of each of the first solid state device and the second solid state device coupled together, the switch first terminal includes a third terminal of the first solid state device, and the switch second terminal includes a third terminal of the second solid state device.

11. The contactor assembly in claim 10 wherein
the first solid state device and the second solid state device are each are each selected from the group consisting of MOSFETs, Bipolar Junction Transistors, JFETs, Insulated Gate Bipolar Junction Transistors or integrated solutions.

12. The contactor assembly in claim 10 wherein,
the first solid state device includes a first N-channel FET and the second solid state device includes a second N-channel FET, the first and second N-channel FET source terminals coupled together, and the switch control terminal includes the first and second N-channel FET gate terminals, the switch first terminal includes the first N-channel FET drain, and the switch second terminal includes the second N-channel FET drain.

13. The contactor assembly in claim 1 wherein,
the switch comprises a plurality of first solid state devices each having at least three terminals and a plurality of second solid state devices each having at least at least three terminals,
one terminal of each of the plurality of first solid state devices and one terminal of each of the plurality of the second solid state devices coupled together, respectively,
the switch control terminal includes at least a second terminal of each of the plurality of first solid state devices and at least a second terminal of each of the plurality of second solid state devices, and
the switch first terminal includes at least a third terminal of each of the plurality of first solid state devices, and the switch second terminal includes at least a third terminal of each of the plurality of second solid state devices.

14. The contactor assembly in claim 13 wherein,
the plurality of first solid state devices and the plurality of second solid state devices are each selected from the group consisting of MOSFETs, BJTs, JFETs, IGBJTs or integrated solutions.

15. The contactor assembly in claim 13 wherein,
the plurality of first solid state devices are a plurality of first N-channel FETs and the plurality of second solid state devices are a plurality of second N-channel FETs, and the switch control terminal comprises the plurality of first N-channel FET gates and the plurality of second N-channel FET gates, the switch first terminal comprises the plurality of the first N-channel FET drains, and the switch second terminal comprises the plurality of the second N-channel FET drains.

16. The contactor assembly in claim 1 wherein,
the contactor first terminal and the contactor second terminal each comprise a metallic conductor, the contactor first terminal has a contactor first terminal interior surface of which a portion comprises a switch terminal mounting surface, the contactor second terminal has a contactor second terminal interior surface of which a portion comprises a switch terminal mounting surface,
the switch comprises a plurality of first solid state devices and a plurality of second solid state devices having at least a first terminal of each of the plurality of first solid state devices and a first terminal of each of the plurality of the second solid state devices coupled together, the switch control terminal comprises a second terminal of each of the plurality of first solid state devices and a second terminal of each of the plurality of second solid state devices, the switch first terminal comprises at least a third terminal of each of the plurality of the first solid state devices, and the switch second terminal comprises at least a third terminal of each of the plurality of second solid state devices, and
the switch first terminal is mounted on the switch terminal mounting surface of the contactor first terminal interior surface at a position adjacent to the switch second terminal that is mounted on the switch terminal mounting surface of the contactor second terminal interior surface.

17. The contactor assembly in claim 16 wherein,
the plurality of first solid state devices are a plurality of first N-channel FETs and the plurality of second solid state devices are a plurality of second N-channel FETs, and the switch control terminal comprises both the plurality of first N-channel FET gates and the plurality of second N-channel FET gates, the switch first terminal comprises the plurality of the first N-channel FET drains, and the switch second terminal comprises the plurality of the second N-channel FET drains, and
the plurality of the first N-channel FET drains are mounted on the contactor first terminal interior surface and the plurality of the second N-channel FET drains are mounted on the contactor second terminal interior surface.

18. The contactor assembly in claim 17 wherein,
the contactor housing is substantially rectangular, and the contactor first terminal interior surface is oriented substantially parallel to the contactor second terminal interior surface.

19. A contactor for a battery module, the battery module comprised of a battery housing, a battery housing terminal, at least one battery cell, and a battery control system with a processor located on a circuit board, the contactor comprising;
a contactor housing separated from the circuit board by a media selected from air and a thermal insulator;
a contactor control terminal that extends through the contactor housing and coupled to the processor, a contactor first terminal comprising a first metallic conductor that extends through the contactor housing and coupled to the battery housing terminal, and a contactor second terminal comprising a second metallic conductor that extends through the contactor housing and is coupled to the at least one battery cell; and
a switch with a switch first terminal and a switch second terminal, and a switch control input, the switch first terminal mounted on the first metallic conductor and the switch second terminal mounted on the second metallic conductor, and the switch control input coupled to the contactor control terminal;
wherein the switch control input is controlled to allow or prohibit current flow between the contactor first terminal and the contactor second terminal.

20. The contactor in claim 19 wherein,
the switch comprises a first solid state device and a second solid state device, the first solid state device and the second solid state device each having at least three terminals with at least a first terminal of the first solid state device and at least a first terminal of the second solid state device coupled together, the switch control input comprises at least a second of the terminals of the first solid state device and at least a second of the terminals the second solid state device, and the switch first terminal comprises at least a third terminal of the first solid state device, and the switch second terminal comprises at least a third terminal of the second solid state device.
